(19) United States
(12) Patent Application Publication
(10) Pub. No.: US 2025/0391641 A1
(43) Pub. Date: Dec. 25, 2025

(54) IMPEDANCE MATCHING MODULE, IMPEDANCE MATCHING CIRCUIT, PLASMA PROCESS SUPPLY SYSTEM AND PLASMA PROCESS SYSTEM

(71) Applicant: TRUMPF Hüttinger GmbH + Co. KG, Freiburg (DE)

(72) Inventor: Birger Nordmann, Herdecke (DE)

(21) Appl. No.: 19/310,981

(22) Filed: Aug. 27, 2025

Related U.S. Application Data
(63) Continuation of application No. PCT/EP2024/054999, filed on Feb. 27, 2024.

(30) Foreign Application Priority Data
Feb. 28, 2023 (DE) 10 2023 104 958.5

(51) Int. Cl. H01J 37/32

(52) U.S. Cl. CPC H01J 37/32183

(57) ABSTRACT

An impedance matching module for an impedance matching circuit, a plasma process supply system and a plasma process system for mounting on a metallic, cooling body, for powers ≥500 W and frequencies from 2 MHz to 100 MHz, including a planar inductor, an insulating circuit board, and a substrate. The planar inductor is divided into two planar conductor tracks electrically connected in parallel and arranged on both sides congruently on the insulating circuit board. The two planar conductor tracks are connected. The substrate is thicker than the insulating circuit board and connected over a majority of an underside of the insulating circuit board. The two planar conductor tracks are configured spaced apart and electrically insulated from a cooling body. The substrate and a connection of the insulating circuit board to the substrate are configured for dissipating heat of the two planar conductor tracks to the cooling body.

### CROSS REFERENCE TO RELATED APPLICATIONS

This application is a continuation of International Application No. PCT/EP2024/054999 (WO 2024/180091 A1), filed on Feb. 27, 2024, and claims benefit to German Patent Application No. DE 10 2023 104 958.5, filed on Feb. 28, 2023. The aforementioned applications are hereby incorporated by reference herein.

### FIELD

The present invention relates to an impedance matching module, an impedance matching circuit, a plasma process supply system and a plasma process system.

### BACKGROUND

An impedance matching module can be used in an impedance matching circuit in a system in which a load is supplied with electrical power, in particular high-frequency power. ‘High frequency’ is also abbreviated to ‘HF’ in the following. HF here refers to frequencies in the range from 2 MHz to 100 MHz, in particular from 10 MHz to 50 MHz.

In such a system, the impedance of the load should be matched to the impedance of the power supply, since otherwise power reflection can occur. The power reflection has a direct impact on the efficiency of a system; it reduces the effectiveness of a system.

An exemplary system in which an impedance matching circuit might be used can be a plasma process system.

Such a plasma process system can, for example, be a system in which a load, e.g., a plasma process arrangement, is supplied with electrical power. Without a connected plasma process arrangement, a plasma process system can be referred to as a plasma process supply system.

A plasma process arrangement can, for example, be a plasma process chamber that is used for industrial plasma processes such as the surface treatment of workpieces, semiconductor manufacturing with plasma, or the processing of workpieces with gas lasers.

In such an application, the plasma process arrangement serves to generate plasma.

For this purpose, a plasma process arrangement can comprise an electrode which is fed with a high-frequency power signal for generating the plasma, hereinafter referred to as the HF power signal.

Typically, a high-power and in particular high-voltage power supply is required, for which the plasma process arrangement can be connected to a high-frequency power supply, hereinafter referred to as HF power supply.

The plasma process taking place in the plasma process arrangement has the problem that the electrical load impedance of the plasma process arrangement, which occurs during the process, depends on the conditions in the plasma process arrangement and can vary greatly. In particular, the properties of the workpiece, electrode, and gas conditions are taken into account.

For this reason, an impedance matching circuit is usually required to transform the impedance of the load to a nominal impedance of the HF power supply. Such an impedance matching circuit is usually placed between an HF power supply and the plasma process arrangement, usually in the immediate vicinity of the plasma process arrangement.

An impedance matching circuit is usually an arrangement that can have inductors and/or capacitors.

The higher the power to be transmitted, the more difficult it becomes to build compact impedance matching circuits. The impedance matching circuits therefore become larger, the greater the power to be transmitted. This size makes the use thereof space-consuming and allows little variability in the construction thereof in many arrangements. A compact design. Thus, one that is designed to save as much space as possible is very desirable.

DE 20 2016 008 958 U1 discloses a solution for reducing installation space and simplifying production for a power combiner. A planar structure is used for the power combiner.

In planar structures, the skin effect occurs in inductors and lines, resulting in unwanted hotspots. These hotspots reduce the efficiency of an impedance matching circuit.

In addition, the quality of inductors and lines used in an impedance matching circuit should generally be maximized, as this is also responsible for the efficiency and thus quality of an impedance matching circuit.

### SUMMARY

In an embodiment, the present disclosure provides an impedance matching module for an impedance matching circuit, a plasma process supply system and a plasma process system for mounting on a metallic, cooling body, for powers ≥500 W and frequencies in the range from 2 MHz to 100 MHz, comprising a planar inductor, an insulating circuit board, and a substrate including a ceramic plate. The planar inductor is divided into two planar conductor tracks of equal length which are electrically connected in parallel and which are arranged on both sides and congruently on the insulating circuit board. The two planar conductor tracks are electrically connected at their ends via terminals and/or vias. The substrate is thicker than the insulating circuit board and is fixedly connected to a surface of the insulating circuit board over a majority of an underside of the insulating circuit board. The two planar conductor tracks are configured to be spaced apart, by way of the substrate, from a cooling body in order to be electrically insulated therefrom. The substrate and a connection of the insulating circuit board to the substrate are configured for dissipating heat of the two planar conductor tracks to the cooling body.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 illustrates a schematic view of an embodiment of an impedance matching module according to the present disclosure arranged on a cooling body in cross-section;

FIG. 2 illustrates a schematic view of a top side of an insulating circuit board of an impedance matching module according to the present disclosure;

FIG. 3 illustrates a schematic view of an embodiment of an underside of an insulating circuit board of an impedance matching module according to the present disclosure;

FIG. 4 illustrates a schematic view of an embodiment of a plasma process system; and

FIG. 5 illustrates a perspective view of an impedance matching module.

### DETAILED DESCRIPTION

In an embodiment, the present disclosure provides an impedance matching module for powers ≥500 W and frequencies in the range from 2 MHz to 100 MHz, which can be realized in a planar structure in the smallest possible space, avoids hotspots and has inductances and lines with high quality.

According to the present disclosure, an impedance matching module for an impedance matching circuit, a plasma process supply system and a plasma process system for mounting on an, in particular metallic, cooling body is proposed, designed for powers ≥500 W and frequencies in the range from 2 MHz to 100 MHz, comprising:
a) a planar inductor,
b) an insulating circuit board,
c) a substrate, in particular a ceramic plate,
d) wherein the planar inductor is divided into two planar conductor tracks of equal length, which are electrically connected in parallel and are arranged on both sides and congruently on the insulating circuit board,
e) wherein the two conductor tracks are electrically connected at their ends via terminals and/or vias, in particular are electrically connected exclusively at the ends thereof,
f) wherein the substrate is thicker than the insulating circuit board and is fixedly connected to the surface of the insulating circuit board over the majority of the underside of the insulating circuit board, and
g) wherein the planar conductor tracks can be spaced apart, by way of the substrate, from a cooling body, in particular a metallic cooling body, to be electrically insulated therefrom, and
h) wherein the substrate and the connection of the printed circuit board to the substrate are configured to dissipate the heat of the planar conductor tracks to a cooling body.

By doubling the conductor tracks on the underside and top side of an insulating circuit board, the current in a planar inductor or line is divided into two paths. Owing to the substantially identical current flow geometry with double the conductor cross-section, the losses are smaller with the same inductance. This results in an inductance with a higher quality. By splitting the current between two lines, local heat points, which are termed hotspots, are avoided. “Substantially identical current flow geometry” means a geometry that represents identical geometric dimensions under typical manufacturing boundary conditions, particularly under typical circuit board manufacturing boundary conditions. Minor modifications to take into account further boundary conditions, such as fastening devices, contacts, safety distances, etc., can also fall under the term “substantially”.

The conductor tracks forming the inductor are made of an electrically conductive material, in particular copper. When selecting the material of the insulating circuit board, it is preferable to ensure that the material is suitable for high-frequency applications. For the insulating circuit board, a typical circuit board material such as, for example, a FR-4 or polytetrafluoroethylene-based material is therefore initially suitable. The polytetrafluoroethylene-based material, also called PTFE material, is particularly suitable due to its low dielectric constant and its low losses. For example, an aluminum oxide or aluminum nitride ceramic can be used for the substrate.

The designation FR-4 stands for a class of flame-retardant and flame-resistant composite materials consisting of epoxy resin and glass fiber fabric. The abbreviation FR stands for “flame retardant”.

Polytetrafluoroethylene-based material, also abbreviated to PTFE material, is many times more expensive than FR-4, but it can be used for circuit boards in the HF range because it has particularly low losses in this frequency range. The circuit boards can be designed to be thinner because this material has a lower dielectric constant and also a higher dielectric strength against high electric fields.

“Fixedly connected” means a connection between the circuit board and the substrate that cannot slip during operation, cannot come loose and in which no air pockets are present or can form. Such air pockets often occur in components connected to thermal paste. These have the disadvantage that high electric fields can arise at the edge of the air inclusions, which in turn can lead to harmful partial discharges. In addition, the thermal conductivity is negatively affected. The ‘fixed connection’ is advantageously produced by pressing and/or adhesive bonding, in particular under pressure combined with heat.

A “majority” means a proportion of the area that makes up at least 60%, in particular at least 80%, of the total area. For example, if the underside of the circuit board is 100 cm², the “majority of the underside” should be at least 60 cm², in particular at least 80 cm².

This provides an impedance matching module that is compact due to the planar design thereof and also avoids the formation of local hot spots and has inductances and lines with high quality.

The two conductor tracks can only be connected to each other at their ends at the terminals and vias. As a result, the current flow is forced to remain in the conductor track, in particular in non-straight sections, and cannot escape to the other one. This improves the quality of the inductance because it reduces the skin effect.

Furthermore, the insulating circuit board and the substrate of the impedance matching module can be connected by heating and pressing together a prepreg inserted therebetween. “Prepreg” is a common material name, which is an abbreviation of “pre-impregnated”. This usually refers to pre-impregnated, mostly planar, flat textile semi-finished products with a thermoplastic or thermosetting matrix, such as unidirectional layers of threads, fabrics or scrims with threads often arranged at right angles.

Prepregs are cured under temperature and pressure to produce components. For example, they are prefabricated in web form, wound on rolls. The term prepreg includes not only unidirectionally reinforced or flat semi-finished products, but also other preforms of basically any shape, which in the broadest sense consist of a fiber-filled, uncured thermosetting matrix. The matrix is in a partially cross-linked state and is pasty to solid, but can be liquefied again by heating.

Prepregs are machine-processable and are therefore often used in automated processes. They produce consistent and high quality. Advantages are the low undulation and high fiber volume content thereof. Curing at high temperatures enables short cycle times in further processing. Processing requires high investment costs, e.g., for autoclaves, laying robots and refrigerated storage. Such prepregs are generally used to join a plurality of circuit boards together to form a multilayer circuit board. To ensure a safe and long-lasting joint, the materials to be joined together should have very similar properties with respect to their expansion when heated. However, this is not necessarily the case with the circuit board and the substrate, in particular if the substrate is made of ceramic. This is an argument initially against such a connection. However, ceramics have very good thermal conductivity and at the same time very good electrical insulating properties and also low dielectric losses when insulating high-frequency signals of high voltage. Contrary to expectations, tests have shown that even with small dimensions, a secure and long-lasting joining together of materials with different properties, such as ceramic with FR-4 and/or ceramic with PTFE material, can be provided. Small dimensions in this context means a bonding area of less than 400 cm² and/or with a maximum length of 20 cm.

The entire impedance matching module can be applied via the substrate to a cooling body, which dissipates the heat from the planar conductor tracks. Such a cooling body can preferably be metallic, in particular made of aluminum and/or copper. The cooling body can further be a fluid cooling body having at least one channel through which a fluid flows, via which the heat is dissipated. A thermal paste can be applied between the cooling body and the substrate and the impedance matching module can be attached to the cooling body using brackets.

Furthermore, the impedance matching module can be used in an impedance matching circuit in a plasma process supply system or a plasma process system.

Such a plasma process supply system can include an HF power supply in addition to the impedance matching circuit.

In addition to the impedance matching module, such an impedance matching circuit can also comprise additional reactances, such as coils and/or capacitors, semiconductor switching elements and a control circuit. The reactances can be connected and disconnected via the semiconductor switching elements to change the impedance from the input to the output of the impedance matching circuit. The semiconductor switching elements can be, for example, metal-oxide-semiconductor field-effect transistors (MOSFETs). The connecting and disconnecting using the semiconductor switching elements can be controlled via the control circuit. The control circuit (16) can be designed for this purpose.

The entire impedance matching circuit can be connected to the HF power supply on the one hand and can be designed to be connected to a plasma process arrangement on the other hand.

In a plasma process system, such a plasma process arrangement can be present and connected to the impedance matching circuit. The plasma process arrangement can be supplied with electrical power, provided by the HF power supply, via the impedance matching circuit.

Exemplary embodiments of the present disclosure are shown schematically in the drawings and are explained in more detail below with reference to the figures.

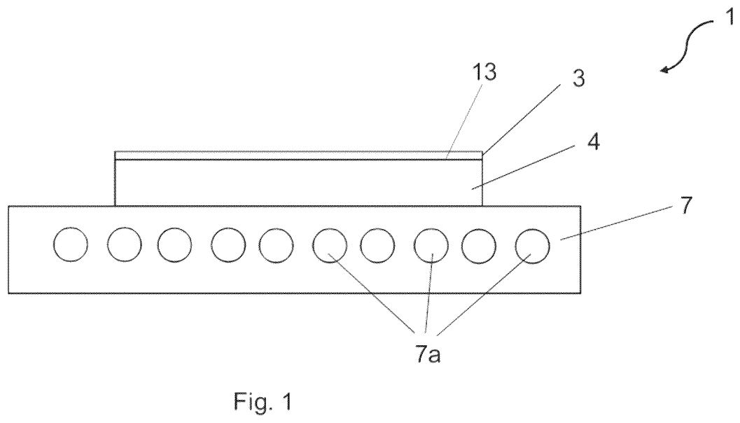

FIG. 1 shows a first embodiment of an impedance matching module 1 according to the present disclosure arranged on a cooling body 7. The insulating circuit board 3 and the substrate 4 of the impedance matching module 1 are also visible in the cross-section shown. The insulating circuit board 3 is arranged on the substrate 4 and connected thereto. The substrate 4 is arranged on the cooling body 7 and connected thereto. Owing to the thickness of the substrate, the insulating circuit board 3 is spaced apart from the cooling body 7 and is electrically insulated therefrom. An inductor 2 is arranged as a planar conductor track 2a on the top side 3a and as a planar conductor track 2b on the underside 3b of the insulating circuit board 3. The cooling body 7 is shown as a fluid cooling body having a plurality of cooling channels 7a which are designed to be flowed through by a fluid, e.g., water, via which heat that arises can be dissipated.

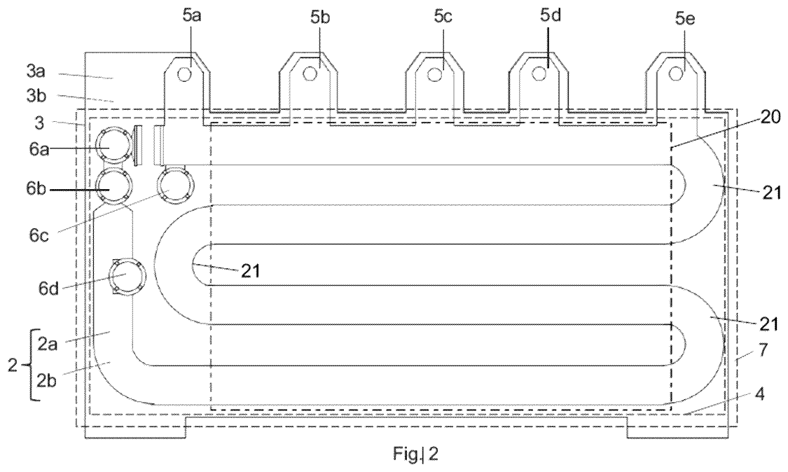

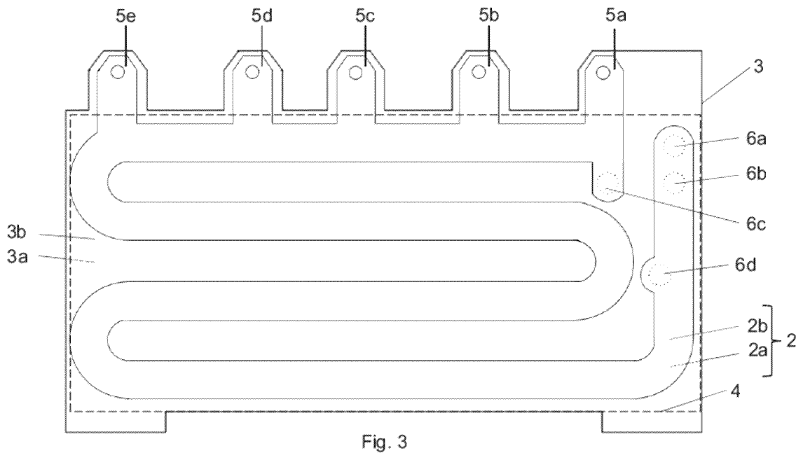

FIG. 2 shows an embodiment of the top side 3a of the insulating circuit board 3 of the impedance matching module 1. This top side 3a of the insulating circuit board 3 has a planar conductor track 2a, terminals 5a, b, c, d, e and vias 6a, b, c, d. The planar inductor 2 has two planar conductor tracks 2a, 2b, of which only one planar conductor track 2a is visible on the top side 3a. The other planar conductor track 2b is arranged substantially congruently on the underside 3b, as shown in FIG. 3. The two planar conductor tracks 2a, 2b have an asymmetric shape, in particular the two conductor tracks 2a, 2b have a meandering course. The planar inductor 2 with the two planar conductor tracks 2a, 2b thereof has straight sections 20 followed by non-straight sections 21, here in particular having a strong curve shape, whereby the planar conductor tracks 2a, 2b reverse their direction. The change of these sections occurs several times in succession, with the curve shapes being alternating right and left curves, so that the planar inductor 2 can utilize the area of the insulated circuit board 3 and has the desired properties.

In addition, terminals 5a, b, c, d, e are located on the top side 3a of the insulating circuit board 3 and are connected to the planar inductor 2. Via these terminals, the impedance matching module 1 can be integrated into an impedance matching circuit 11. The vias 6a, b, c, d, which have a round shape, serve to electrically connect the planar inductor 2 on the top side 3a of the insulating circuit board 3 with the planar inductor on the underside 3b. For example, terminals for an HF power signal can also be applied to the vias 6a, b, c, d of the top side 3a of the insulating circuit board 3.

FIG. 3 shows an embodiment of an underside 3b of the insulating circuit board 3 of the impedance matching module 1. The underside 3b represents the rear side of the top side 3a described in FIG. 2 and therefore has the same components. The description of the components can therefore be taken from the description of FIG. 2. The fundamental distinction between the top side and underside of the insulating circuit board 3 is that in the top view the planar conductor track 2b on the underside 3b is arranged to be mirror-inverted with respect to the planar conductor track 2a on the top side 3a. This results in the two planar conductor tracks 2a, 2b being arranged exactly one above the other, i.e., congruent, but electrically separated by the circuit board 3.

The terminals 5a, 5b, 5c, 5d, 5e can each constitute an end of the conductor tracks 2a, 2b. They provide the possibility of adjusting the desired inductance or matching it to the frequency by connecting the following components of an impedance matching circuit 11 to one of the corresponding terminals 5a, 5b, 5c, 5d, 5e.

The vias 6a, 6b, 6c, 6d can each constitute an end of the conductor tracks 2a, 2b. They serve to balance the desired inductance or to match it to the frequency by connecting additional components of an impedance matching circuit 11 to one of the corresponding vias 6a, 6b, 6c, 6d.

The two conductor tracks 2a, 2b are only connected to each other at the terminals 5a, 5b, 5c, 5d, 5e and vias 6a, 6b, 6c, 6d. As a result, the current flow, in particular in the non-straight sections 21, is forced to remain in the conductor track 2a, 2b and cannot escape to the other one. This improves the quality of the inductance because it reduces the skin effect.

In FIGS. 2 and 3, the position of a substrate 4 is also indicated as a dashed border.

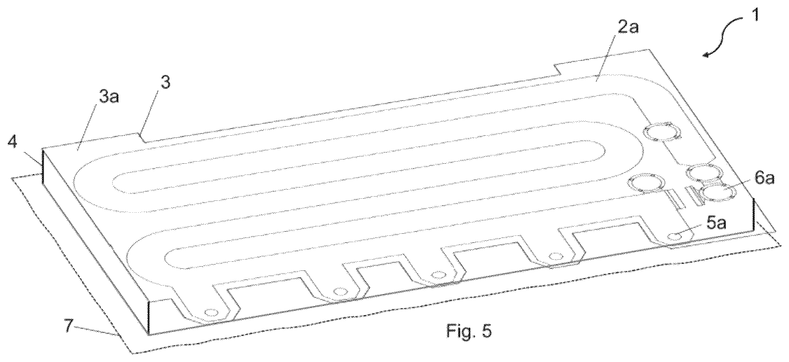

FIG. 5 shows a perspective view of the impedance matching module 1. The same reference signs are used here as in FIGS. 1, 2, and 3.

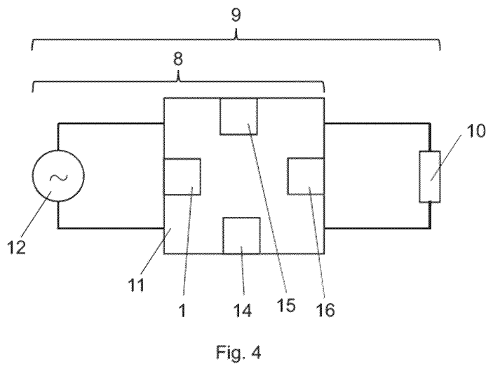

FIG. 4 shows an embodiment of an exemplary plasma process system 9. The plasma process system 9 comprises a plasma process supply system 8 and a plasma process arrangement 10. The plasma process supply system 8 comprises an impedance matching circuit 11 and an HF power supply 12. The impedance matching module 1 according to the present disclosure is integrated into the impedance matching circuit 11. In addition, the impedance matching circuit 11 comprises additional reactances 14, such as capacitors and/or coils, semiconductor switching elements 15 and a control circuit 16.

Such a typical impedance matching circuit 11 is described, for example, in patent application DE 10 2023 104 942.9 filed on Feb. 28, 2023 with the title “Impedance matching circuit, plasma process supply system and plasma process system”, which is hereby fully incorporated by reference into the present application. In particular, the additional impedance matching circuit (1) described in the said application can further develop the present impedance matching circuit 11 with individual or all of the features thereof.

Such a typical plasma process system 9 is described, for example, in patent application DE 10 2023 104 955.0 filed on Feb. 28, 2023, entitled “Impedance matching circuit for a plasma process system and a plasma process system with such an impedance matching circuit”, which is hereby fully incorporated by reference into the present application. In particular, at least one of the coils (15, 18, 19, 24, 25) described in the said patent application can be designed with the features of the impedance matching module 1 described here.

Such a typical plasma process system 9 is also described, for example, in patent application DE 10 2023 104 948.8 filed on Feb. 28, 2023, entitled “Impedance matching circuit, plasma process supply system and plasma process system”, which is hereby fully incorporated by reference into the present application. In particular, at least one of the inductors (L2a, L2b, L3a, L3d, L3e, L3f) described in the said patent application can be designed with the features of the impedance matching module 1 described here.

With the features described above, the number of components, such as semiconductor switching elements or reactances, such as coils and/or capacitors, as well as capacitances and/or inductances can be kept lower, thus achieving an even more compact design.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. An impedance matching module for an impedance matching circuit, a plasma process supply system and a plasma process system for mounting on a metallic, cooling body, for powers ≥500 W and frequencies in the range from 2 MHz to 100 MHz, comprising:
a) a planar inductor;
b) an insulating circuit board; and
c) a substrate including a ceramic plate,
d) wherein the planar inductor is divided into two planar conductor tracks of equal length which are electrically connected in parallel and which are arranged on both sides and congruently on the insulating circuit board,
e) wherein the two planar conductor tracks are electrically connected at their ends via terminals and/or vias,
f) wherein the substrate is thicker than the insulating circuit board and is fixedly connected to a surface of the insulating circuit board over a majority of an underside of the insulating circuit board,
g) wherein the two planar conductor tracks are configured to be spaced apart, by way of the substrate, from a cooling body in order to be electrically insulated therefrom, and
h) wherein the substrate and a connection of the insulating circuit board to the substrate are configured for dissipating heat of the two planar conductor tracks to the cooling body.

2. The impedance matching module according to claim 1, wherein the substrate is connected to the insulating circuit board via a prepreg inserted therebetween by heating and pressing together.

3. The impedance matching module according to claim 1, wherein the impedance matching module is connected to the cooling body, which is a metallic cooling body, via the substrate.

4. The impedance matching module according to claim 3, wherein the cooling body is a fluid cooling body which has at least one cooling channel through which a fluid flows, via which the heat is configured to be dissipated.

5. The impedance matching module according to claim 1, wherein the connection of the insulating circuit board to the substrate is produced by pressing and/or adhesive bonding under pressure combined with heat.

6. The impedance matching module according to claim 1, wherein the two planar conductor tracks are connected to one another exclusively at their ends at the terminals and vias.

7. The impedance matching module according to claim 1, wherein the two planar conductor tracks have a meandering course.

8. The impedance matching module according to claim 1, wherein the two planar conductor tracks have a plurality of terminals along their course, each of which is configured for connecting additional components and can thus each constitute an end of the two planar conductor tracks.

9. The impedance matching module according to claim 1, wherein the two planar conductor tracks have a plurality of vias along the course thereof, each of which is configured for connecting additional components and can thus each constitute an end of the conductor tracks.

10. An impedance matching circuit, comprising:
a) the impedance matching module according to claim 1;
b) additional reactances, e.g., capacitors and/or coils;
c) semiconductor switching elements including transistors or PIN diodes; and
d) a control circuit,
e) wherein the semiconductor switching elements are configured to connect and disconnect the reactances in order to change an impedance from an input to an output of the impedance matching circuit, and
f) wherein the control circuit is configured to control connecting and disconnecting of the reactances by the semiconductor switching elements.

11. The impedance matching circuit according to claim 10, configured to be connected to a high frequency (HF) power supply and to a plasma process arrangement.

12. A plasma process supply system comprising:
an HF power supply for providing an HF power signal; and
the impedance matching circuit according to claim 10, wherein the impedance matching circuit is electrically connected to the HF power supply and is configured to be connected to a plasma process arrangement.

13. The plasma process system comprising the plasma process supply system according to claim 12 and a plasma process arrangement, wherein the plasma process arrangement is connected to the plasma process supply system and the plasma process supply system is configured to supply the plasma process arrangement with power of an HF power signal.
